(19) United States
(12) Patent Application Publication
(10) Pub. No.: US 2015/0187979 A1
(43) Pub. Date: Jul. 2, 2015

(54) HETEROJUNCTION SOLAR CELL WITH EPITAXIAL SILICON THIN FILM AND METHOD FOR PREPARING THE SAME

(71) Applicant: ATOMIC ENERGY COUNCIL - INSTITUTE OF NUCLEAR ENERGY RESEARCH, TAOYUAN COUNTY (TW)

(72) Inventors: CHUN-YAO HOU, TAOYUAN COUNTY (TW); TSUN-NENG YANG, TAOYUAN COUNTY (TW)

(73) Assignee: ATOMIC ENERGY COUNCIL - INSTITUTE OF NUCLEAR ENERGY RESEARCH, TAOYUAN COUNTY (TW)

(21) Appl. No.: 14/141,595

(22) Filed: Dec. 27, 2013

(51) Int. Cl. H01L 31/0747; H01L 31/18; H01L 31/0224

(52) U.S. Cl. CPC H01L 31/0747; H01L 31/022425; H01L 31/1804

(57) ABSTRACT

A heterojunction solar cell with an epitaxial silicon thin film and a method for preparing the same are revealed. Low-cost upgraded metallurgical grade silicon (UMG-Si) wafers have been used as the substrates to manufacture solar cells so as to reduce the amount of high-purity silicon materials used. First an epitaxial silicon thin film is disposed over a UMG-Si wafer. Then other layers such as an amorphous silicon thin film, a transparent conductive film, etc. are arranged to form a solar cell having heterojunction with an intrinsic thin-layer (HIT) structure. Due to reduce in using high-purity silicon materials, the manufacturing cost of the heterojunction solar cell with an epitaxial silicon thin film is significantly decreased.

### BACKGROUND OF THE INVENTION

1. Fields of the Invention

The present invention relates to a solar cell and a method for preparing the same, especially to a heterojunction solar cell with an epitaxial silicon thin film and a method for preparing the same in which an upgraded metallurgical grade silicon (UMG-Si) wafer with lower-purity silicon is used as a substrate.

2. Descriptions of Related Art

Most of world energy people used is derived from sources fossil energy such as fuel oil and gasoline. Due to the increasing of population and the advancing in human civilization, the demand for energy is stronger, so that the price of petroleum also increased year-by-year. Moreover, the use of fossil energy causes gas emissions that contribute to the enhanced greenhouse effect. Thus the development of renewable energy is becoming an important issue. Although nuclear fission is used to generate electricity, it causes many problems such as radioactive pollution, nuclear waste storage, biohazards and environmental hazards. There is no solution available now.

Compared with other renewable resources such as wind power, geothermal etc., solar energy is one of the most prosperous renewable energy sources that can replace fossil energy. Thus a plurality of research teams worldwide has dedicated to develop low cost solar cells with high energy conversion efficiency. The mass-produced solar cells nowadays are made from silicon bulk materials such as monocrystalline silicon (c-Si) wafer-based or polycrystalline silicon (poly-Si) wafer-based materials. However, high-purity c-Si and poly-Si materials are both produced in high temperature environment. This results in high cost of silicon solar cells.

The Japanese company-Sanyo Ltd. has developed a structure of solar cell called heterojunction with intrinsic thin layer (HIT). A single crystalline silicon wafer being passivated by a layer of intrinsic amorphous silicon (a-Si(i)) and then an n-type or p-type amorphous silicon layer is deposited thereover. The HIT structure can be a single-sided type or a double-sided type. The double-sided heterojunction solar cell includes an intrinsic amorphous silicon layer and an n-type or p-type amorphous silicon layer deposited on a rear side. All the manufacturing processes are performed in an environment with the temperature lower than 200° C. Thus the low-temperature manufacturing processes are energy saving and the quality of silicon materials is also ensured. However, such structure requires float zone crystalline silicon (FZ-c-Si) with high quality and high cost so as to get high energy conversion efficiency.

As mentioned above, it can be concluded that there is a need to provide a structure of solar cells and a method for manufacturing the same by which the amount of high-quality and high-cost silicon materials used is decreased and manufacturing cost of the solar cell is further reduced.

### SUMMARY OF THE INVENTION

Therefore it is a primary object of the present invention to provide a heterojunction solar cell with an epitaxial silicon thin film in which an upgraded metallurgical grade silicon (UMG-Si) wafer is used as a substrate of the solar cell. Thus the amount of high-purity silicon materials used is reduced and the manufacturing cost is dramatically decreased.

It is another object of the present invention to provide a heterojunction solar cell with an epitaxial silicon thin film in which an epitaxial silicon thin film is disposed over a UMG-Si wafer. The solar cell with the UMG-Si wafer and the epitaxial silicon thin film has good energy conversion efficiency.

It is a further object of the present invention to provide a method for preparing a heterojunction solar cell with an epitaxial silicon thin film in which a UMG-Si wafer is used as a core and each layer is gradually deposited over the UMG-Si wafer so as to construct a heterojunction solar cell with an epitaxial silicon thin film having high energy conversion efficiency.

It is a further object of the present invention to provide a method for preparing a heterojunction solar cell with an epitaxial silicon thin film that is applied to both single sided and double sided heterojunction solar cells with an epitaxial silicon thin film. The method has broad applications.

In order to achieve the above objects, a heterojunction solar cell with an epitaxial silicon thin film and a method for preparing the same are provided by the present invention. The heterojunction solar cell with an epitaxial silicon thin film includes a rear-side electrode, an upgraded metallurgical grade silicon (UMG-Si) wafer disposed over the rear-side electrode, an epitaxial silicon thin film deposited over the UMG-Si wafer, a first amorphous silicon thin film arranged over the epitaxial silicon thin film, a first transparent conductive film set over the first amorphous silicon thin film, and a front-side electrode disposed over the first transparent conductive film. According to the above structure and a corresponding method for preparing the same, the cost is down by using the UMG-Si wafer as a core of the heterojunction solar cell with an epitaxial silicon thin film.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a schematic drawing showing structure of a single sided heterojunction solar cell with an epitaxial silicon thin film according to the present invention;

FIG. 2 is a schematic drawing showing structure of a double sided heterojunction solar cell with an epitaxial silicon thin film according to the present invention;

FIG. 3 is a flow chart showing steps of a method for preparing a solar cell according to the present invention;

FIG. 4 is a schematic drawing showing structure of a single sided heterojunction solar cell with an epitaxial silicon thin film and having an intrinsic amorphous silicon thin film according to the present invention;

FIG. 5 is a schematic drawing showing structure of a double sided heterojunction solar cell with an epitaxial silicon thin film and having an intrinsic amorphous silicon thin film according to the present invention.

### DETAILED DESCRIPTION OF THE PREFERRED EMBODIMENT

In order to have better understanding of features and functions of the present invention, refer to following embodiments with details.

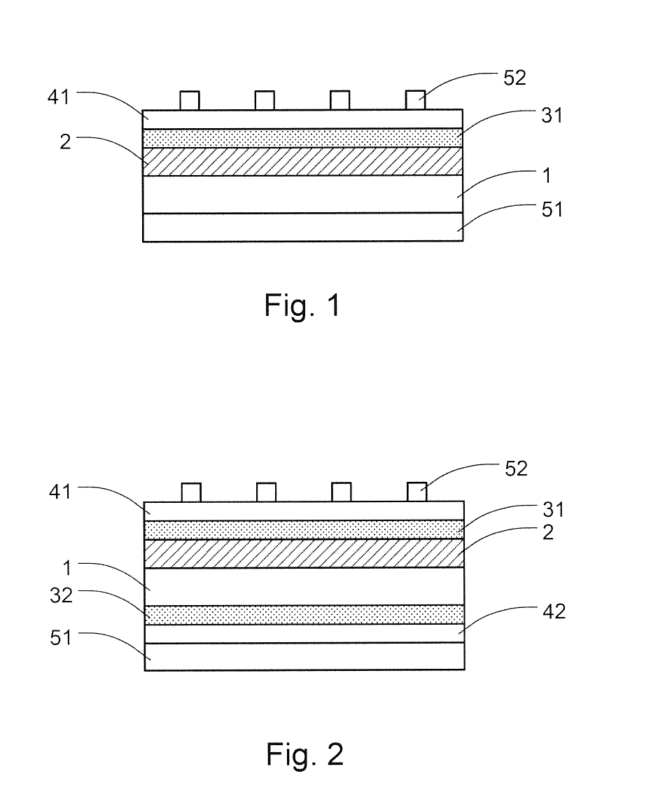

Refer to FIG. 1, a single sided heterojunction solar cell with an epitaxial silicon thin film according to the present invention includes an upgraded metallurgical grade silicon (UMG-Si) wafer 1, an epitaxial silicon thin film 2, a first amorphous silicon thin film 31, a first transparent conductive film 41, a rear-side electrode 51 and a front-side electrode 52. The epitaxial silicon thin film 2 is disposed over the UMG-Si wafer 1 and the first amorphous silicon thin film 31 is arranged over the epitaxial silicon thin film 2. The first transparent conductive film 41 is set over the first amorphous silicon thin film 31 while the rear-side electrode 51 and the front-side electrode 52 are respectively disposed under the UMG-Si wafer 1 and over the transparent conductive film 41.

As to a design of a double sided heterojunction solar cell with an epitaxial silicon thin film, the cross sectional view is shown in FIG. 2. A second amorphous silicon thin film 32 and a second transparent conductive film 42 are arranged under the UMG-Si wafer 1 sequentially and then the rear-side electrode 51 is disposed.

Instead of a solar grade silicon substrate with purity up to 99.99998%, a silicon substrate used in the present invention is the UMG-Si wafer 1 with a thickness of about 200 micrometers, the purity ranging from 99.9% to 99.999% and lower cost. Thus manufacturing cost of thin film epitaxial silicon solar cells is dramatically reduced.

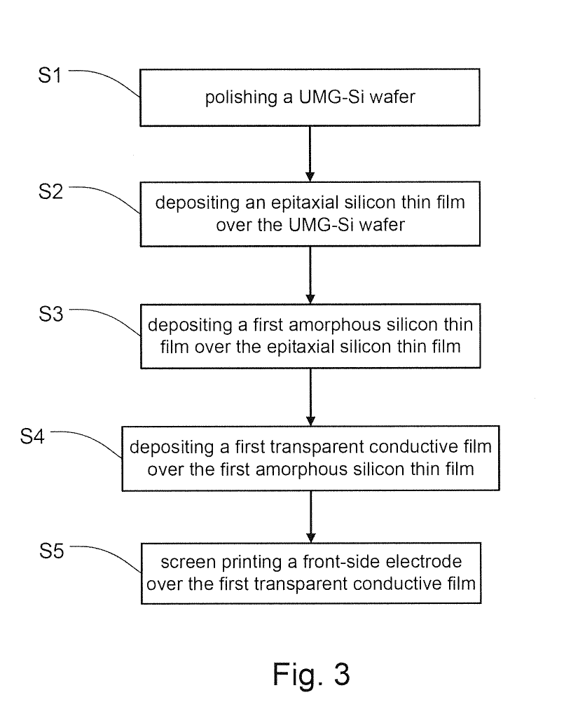

Refer to FIG. 3, a method for preparing a heterojunction solar cell with an epitaxial silicon thin film includes following steps:
Step S1: polishing a UMG-Si wafer;
Step S2: depositing an epitaxial silicon thin film over the UMG-Si wafer;
Step S3: depositing a first amorphous silicon thin film over the epitaxial silicon thin film;
Step S4: depositing a first transparent conductive film over the first amorphous silicon thin film; and
Step S5: screen printing a front-side electrode over the first transparent conductive film.

Refer to step S1, the UMG-Si wafer 1 used as a main body of crystalline silicon solar cells can be n-type or p-type. During preparation processes, mechanical damage on the surface of the UMG-Si wafer 1 occurs due to wire cutting. Thus the wafer needs to be polished before use. In the present invention, the UMG-Si wafer 1 is immersed in at least one acid solution for polishing. The acid solution is selected from one of the following acids: hydrofluoric acid (HF), nitric acid (HNO₃), sulfuric acid (H₂SO₄), hydrochloric acid (HCl) and acetic acid (CH₃COOH). After being soaked in acid solutions and washed by deionized water several times, the surface layer with the mechanical damage is removed and the polishing is completed.

Then an epitaxial silicon thin film 2 is grown on one side of the polished UMG-Si wafer 1. The epitaxial silicon thin film 2 can be an intrinsic layer or a doped layer corresponding to the doping type of the UMG-Si wafer 1. For example, the epitaxial silicon thin film 2 deposited is n-type while the UMG-Si wafer 1 is n-type.

After the epitaxial silicon thin film 2 being deposited on surface of the UMG-Si wafer 1, the function provided by the combination is equal to the function of the solar grade silicon substrate with the purity of 99.99998%. Thus the problem of poor energy conversion efficiency caused by using the UMG-Si wafer 1 with lower quality as the substrate is solved. The manufacturing cost is also reduced.

In the present invention, a surface of the epitaxial silicon thin film 2 is further textured. That means a rough structure is formed on surface of the epitaxial silicon thin film 2. Due to the rough structure, light entering the silicon bulk is reflected multiple times so that light absorption is facilitated.

Instead of conventional thermal diffusion processes of phosphorus, the deposition of the amorphous silicon thin film layer is carried out directly in the present invention. Take the single sided heterojunction solar cell with an epitaxial silicon thin film as an example, the rear-side electrode 51 is disposed before the arrangement of the amorphous silicon thin film layer. Aluminum is deposited under the UMG-Si wafer 1 by screening printing of aluminum paste or evaporation so as to form the rear-side electrode 51.

If the rear-side electrode 51 is disposed by screen printing, it needs to be heated and sintered so as to make the aluminum paste turn into a solid metal layer. Once the rear-side electrode 51 is arranged by evaporation, only annealing is needed while heating or sintering is not required for preparation of the rear-side electrode 51.

In the single sided heterojunction solar cell with an epitaxial silicon thin film, a first amorphous silicon thin film 31 is deposited on a single side of the epitaxial silicon thin film 2 after the preparation of the rear-side electrode 51 being completed. The type of the first amorphous silicon thin film 31 is different from the doping type of the epitaxial silicon thin film 2. The first amorphous silicon thin film 31 deposited is n-type if the epitaxial silicon thin film 2 is p-type, and vice versa. If the epitaxial silicon thin film 2 is an intrinsic layer, the doping type of the first amorphous silicon thin film 31 is different from the doping type of the UMG-Si wafer 1.

Once the target prepared is the double sided heterojunction solar cell with an epitaxial silicon thin film, the preparation of the rear-side electrode 51 is not performed first and the amorphous silicon thin film is deposited on both sides. Besides the first amorphous silicon thin film 31 deposited over the epitaxial silicon thin film 2, a second amorphous silicon thin film 32 is deposited under the UMG-Si wafer 1 at the same time. The first amorphous silicon thin film 31 and the second amorphous silicon thin film 32 have the same doping type.

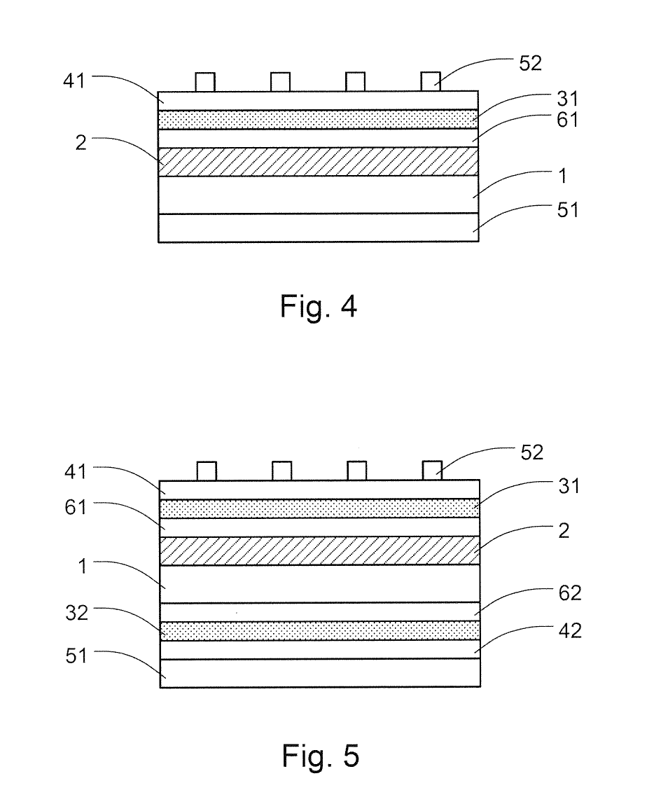

Refer to FIG. 4 and FIG. 5, schematic drawings showing structure of the single sided heterojunction solar cell with an epitaxial silicon thin film and the double sided heterojunction solar cell with an epitaxial silicon thin film are disclosed. Before deposition of the amorphous silicon thin film, an intrinsic amorphous silicon thin film is deposited in advance. That means a first intrinsic amorphous silicon thin film 61 exists between the epitaxial silicon thin film 2 and the first amorphous silicon thin film 31. Moreover, a second intrinsic amorphous silicon thin film 62 is arranged between the UMG-Si wafer 1 and the second amorphous silicon thin film 32.

The layer deposited over the amorphous silicon thin film is a transparent conductive film made from transparent conductive oxide (TCO). As the structure shown in FIG. 1 and FIG. 2, the solar cell includes a first transparent conductive film 41 located over the first amorphous silicon thin film 31. Refer to FIG. 4 and FIG. 5, in the double sided heterojunction solar cell with an epitaxial silicon thin film and having both sides being deposited, a second transparent conductive film 42 is formed under the second amorphous silicon thin film 32. The most common material for the transparent conductive film is indium tin oxide (ITO), but not limited to ITO. Other transparent conductive materials can also be used to be deposited.

After completing the preparation of the films mentioned above, the arrangement of electrodes is performed. In the single sided heterojunction solar cell with an epitaxial silicon thin film, the rear-side electrode 51 has already been disposed. As to the double sided heterojunction solar cell with an epitaxial silicon thin film, the same method is used for preparation of the electrode. In the present invention, the front-side electrode 52 is prepared by screen printing of silver paste for protecting other thin films already disposed from being damaged by high temperature. The silver paste is heated by a low-temperature process (dried at the temperature lower than 200 degrees Celsius) or a room-temperature process. A vertical dryer or an IR belt dryer is used to heat and dry the silver paste.

The followings are the details of single sided/double sided heterojunction solar cell with an epitaxial silicon thin film.

[Double Sided Heterojunction Solar Cell with an Epitaxial Silicon Thin Film]
1. Immerse a UMG-Si wafer into a mixed solution prepared by hydrofluoric acid (HF), nitric acid (HNO₃), and acetic acid (CH₃COOH) mixed in a ratio of 3:5:3 until the surface of the wafer being polished. It takes about 10 to 30 seconds. Then take the UMG-Si wafer out and wash the wafer with deionized water (DI water) for about 10 seconds. Next soak the wafer in potassium hydroxide (KOH) solution with a weight percentage of 2% for about 10 seconds and take the wafer out so as to neutralize the acid. Later immerse the UMG-Si wafer in a solution prepared by hydrofluoric acid (HF) and water (H₂O) mixed in a ratio of 10:1 for about 10 seconds and take the wafer out. Then soak the UMG-Si wafer in a solution prepared by sulfuric acid (H₂SO₄) and hydrogen peroxide (H₂O₂) mixed in a ratio of 10:1 for about 10 minutes and take the wafer out. Again immerse the UMG-Si wafer in a solution prepared by hydrofluoric acid (HF) and water (H₂O) mixed in a ratio of 10:1 for about 10 seconds and take the wafer out. Wash the UMG-Si wafer with DI water for about 10 seconds. Next immerse a UMG-Si wafer into a mixed solution prepared by hydrochloric acid (HCl), hydrogen peroxide (H₂O₂), and water (H₂O) mixed in a ratio of 1:1:6 and the temperature of the mixed solution is 80 degrees Celsius. Then move the wafer out after being immersed for about 10 minutes. Again wash the UMG-Si wafer with DI water for about 10 seconds, immerse the UMG-Si wafer in a solution prepared by hydrofluoric acid (HF) and water (H₂O) mixed in a ratio of 10:1 for about 10 seconds, and take the wafer out. The treatment for removing mechanical damage on surface of the wafer caused by cutting has been completed.
2. Set the UMG-Si wafer in an atmospheric pressure chemical vapor deposition (APCVD) machine. The main stream is hydrogen gas with Si₂H₂Cl₂ flow rate of 10˜30 sccm to deposit an intrinsic silicon thin layer when the deposition temperature is ranging from 1100° C. to 1150° C. The thickness of the silicon thin layer is about 15˜30 μm. If the silicon thin layer is n-type or p-type, additional gas such as PH₃ or B₂H₆ is introduced. After the manufacturing processes being completed and the temperature being decreased, take out the UMG-Si wafer.
3. Set the UMG-Si wafer into a plasma-enhanced chemical vapor deposition (PECVD) machine. Introduce hydrogen gas and turn on a radio frequency (RF) generator to produce plasma. After being treated by hydrogen plasma for about 5 to 30 minutes, put the UMG-Si wafer into a reactive ion etching (RIE) machine. Then introduce gases including oxygen (O₂) and tetrafluoromethane (CF₄), and turn on the RF generator to generate plasma and perform reactive ion etching for about 5 to 30 minutes. After the manufacturing processes being completed, take out the UMG-Si wafer.
4. Put the UMG-Si wafer into the PECVD machine. Introduce gases including silicon hydride (SiH₄) and hydrogen (H₂) to deposit an intrinsic amorphous silicon layer when the deposition temperature is ranging from 180° C. to 220° C. If the amorphous silicon layer deposited is n-type or p-type, additional gas PH₃ or B₂H₆ is introduced. The detailed process parameters are shown below. After the manufacturing processes being completed and the temperature decreased to room temperature, take out the UMG-Si wafer.

| | i-a-Si: H | p-a-Si: H | n-a-Si: H |
|---|---|---|---|
| H₂ (sccm) | 0 | 40 | 100 |
| 10% SiH₄/Ar (sccm ) | 89.6 | 90 | 50 |
| 1% B₂H₆/H₂ (sccm) | 100 | 0 | 0 |
| 1% PH₃/H₂ (sccm) | 0 | 0 | 20 |

| | |
|---|---|
| temperature (° C. ) | 180~220 |
| RF power (W) | 10~30 |
| pressure (torr) | 0.5~1 |
| thickness (Å) | 50~150 |

5. Set the UMG-Si wafer into a sputter machine and put ITO target into the sputter machine. A sample stage is adjusted to the rotation mode. When the deposit temperature is ranging from 150° C. to 220° C., introduce argon gas with a flow rate of 30 sccm and turn on the RF generator. Then the power of the RF generator is slowly increased to 100˜200 W. The thickness of the layer deposited is about 700˜900 Å. After the manufacturing processes being completed and the temperature decreased to room temperature, take out the UMG-Si wafer.
6. Put the UMG-Si wafer into a screen printing machine. Use a low temperature silver paste with a mesh number of 280 and an emulsion thickness of 18 μm for screen printing. After completing the processes, take out the UMG-Si wafer.
7. Set the UMG-Si wafer into a vertical dryer. The temperature and the process time are respectively set at 130˜180° C. and 5˜60 mins. After the process being completed and the temperature decreased to room temperature, take out the UMG-Si wafer. Therefore all manufacturing processes of the solar cell component have been completed.

[Single Sided Heterojunction Solar Cell with an Epitaxial Silicon Thin Film]

The step 1, step 2 and step 3 are the same with the above double sided heterojunction solar cell with an epitaxial silicon thin film.
4. Put the UMG-Si wafer into a screen printing machine. Use aluminum paste (or low temperature silver paste) with a mesh number from 200 to 250 and an emulsion thickness of 20 μm for screen printing. After completing the processes, take out the UMG-Si wafer.
5. Set the UMG-Si wafer into a vertical dryer. The temperature and the process time are respectively set at 180˜200° C. and 6˜12 mins. After the process being completed and the temperature decreased, take out the UMG-Si wafer. Then put the UMG-Si wafer into a rapid thermal annealing (RTA) machine. The peak temperature is 750˜880° C. while the gas introduced is air or only oxygen. After the process being completed and the temperature decreased to room temperature, take out the UMG-Si wafer.
   Next perform the step 4˜7 for preparing the double sided heterojunction solar cell with an epitaxial silicon thin film mentioned above, manufacturing processes of the solar cell component have been completed.

In summary, the present invention makes use of the UMG-Si wafer. An epitaxial silicon thin film is grown on the UMG-Si wafer so as to reduce the amount of high-purity silicon materials used. Moreover, the efficiency of the solar cell reaches a certain level as the conventional crystalline silicon-based solar cell. Thereby, given the development potential of enhancing performance and saving cost, the present invention undoubtedly provides a heterojunction solar cell with an epitaxial silicon thin film and a method for preparing the same having utility and commercial values.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A heterojunction solar cell with an epitaxial silicon thin film comprising:
a rear-side electrode;
an upgraded metallurgical grade silicon (UMG-Si) wafer disposed over the rear-side electrode;
an epitaxial silicon thin film deposited over the UMG-Si wafer;
a first amorphous silicon thin film arranged over the epitaxial silicon thin film;
a first transparent conductive film set over the first amorphous silicon thin film; and
a front-side electrode disposed over the first transparent conductive film.

2. The device as claimed in claim 1, wherein between the rear-side electrode and the UMG-Si wafer, the heterojunction solar cell further includes:
a second amorphous silicon thin film arranged under the UMG-Si wafer; and
a second transparent conductive film disposed under the second amorphous silicon thin film and over the rear-side electrode.

3. The device as claimed in claim 1, wherein the heterojunction solar cell further includes a first intrinsic amorphous silicon thin film arranged between the epitaxial silicon thin film and the first amorphous silicon thin film.

4. The device as claimed in claim 2, wherein the heterojunction solar cell further includes a second intrinsic amorphous silicon thin film disposed between the UMG-Si wafer and the second amorphous silicon thin film.

5. A method for preparing a heterojunction solar cell with an epitaxial silicon thin film comprising the steps of:
polishing an upgraded metallurgical grade silicon (UMG-Si) wafer;
depositing an epitaxial silicon thin film over the UMG-Si wafer;
depositing a first amorphous silicon thin film over the epitaxial silicon thin film and a second amorphous silicon thin film under the UMG-Si wafer at the same time;
depositing a first transparent conductive film over the first amorphous silicon thin film and a second transparent conductive film under the second amorphous silicon thin film at the same time; and
screen printing a front-side electrode over the first transparent conductive film and a rear-side electrode under the second transparent conductive film respectively.

6. The method as claimed in claim 5, wherein in the step of polishing an UMG-Si wafer, the UMG-Si wafer is immersed in at least one acid solution.

7. The method as claimed in claim 6, wherein the acid solution is selected from the group consisting of hydrofluoric acid (HF), nitric acid (HNO₃), sulfuric acid (H₂SO₄), hydrochloric acid (HCl) and acetic acid (CH₃COOH).

8. The method as claimed in claim 5, wherein after the step of depositing an epitaxial silicon thin film over the UMG-Si wafer, the method further includes a step of texturing a surface of the epitaxial silicon thin film.

9. A method for preparing a heterojunction solar cell with an epitaxial silicon thin film comprising the steps of:
polishing an upgraded metallurgical grade silicon (UMG-Si) wafer;
depositing an epitaxial silicon thin film over the UMG-Si wafer;
disposing a rear-side electrode under the UMG-Si wafer;
depositing a first amorphous silicon thin film over the epitaxial silicon thin film;
depositing a first transparent conductive film over the first amorphous silicon thin film; and
screen printing a front-side electrode over the first transparent conductive film.

10. The method as claimed in claim 9, wherein in the step of disposing a rear-side electrode under the UMG-Si wafer, screen printing or evaporation is used.
